(19) United States
(12) Patent Application Publication
(10) Pub. No.: US 2026/0173958 A1
(43) Pub. Date: Jun. 18, 2026

(54) PACKAGE COMPRISING INTEGRATED DEVICES AND PASSIVE DEVICES

(71) Applicant: QUALCOMM Incorporated, San Diego, CA (US)

(72) Inventors: Ranadeep DUTTA, Del Mar, CA (US); Jonghae KIM, San Diego, CA (US); Je-Hsiung LAN, San Diego, CA (US)

(21) Appl. No.: 18/984,924

(22) Filed: Dec. 17, 2024

(51) Int. Cl. H01L 25/16; H01L 21/48; H01L 21/56; H01L 23/00; H01L 23/538; H01L 23/64

(52) U.S. Cl. CPC H10W 90/00; H10W 44/501; H10W 70/05; H10W 70/611; H10W 70/65; H10W 70/685; H10W 74/016; H10W 72/07236; H10W 74/10; H10W 90/724; H10W 90/728

(57) ABSTRACT

A package comprising a substrate; a first integrated device coupled to the substrate through at least a first plurality of solder interconnects; an encapsulation layer at least partially encapsulating the first integrated device, wherein the encapsulation layer includes a cavity; a metallization portion coupled to the first integrated device; and a first passive device coupled to the metallization portion through at least a second plurality of solder interconnects, wherein the first passive device is located at least partially in the cavity of the encapsulation layer.

### FIELD

Various features relate to packages with integrated devices and passive devices.

### BACKGROUND

A package may include a substrate and integrated devices. These components are coupled together to provide a package that may perform various electrical functions. There is an ongoing need to provide better performing packages. Moreover, there is also an ongoing need to reduce and/or minimize the overall size of the packages.

### SUMMARY

Various features relate to packages with integrated devices and passive devices.

One example provides a package comprising a substrate; a first integrated device coupled to the substrate through at least a first plurality of solder interconnects; an encapsulation layer at least partially encapsulating the first integrated device, wherein the encapsulation layer includes a cavity; a metallization portion coupled to the first integrated device; and a first passive device coupled to the metallization portion through at least a second plurality of solder interconnects, wherein the first passive device is located at least partially in the cavity of the encapsulation layer.

Another example provides a method for fabricating a package. The method provides a substrate. The method couples a first integrated device to the substrate through at least a first plurality of solder interconnects. The method forms an encapsulation layer that at least partially encapsulates the first integrated device, wherein the encapsulation layer includes a cavity. The method forms a metallization portion that is coupled to the first integrated device. The method couples a first passive device to the metallization portion through at least a second plurality of solder interconnects, wherein the first passive device is located at least partially in the cavity of the encapsulation layer.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes integrated devices, an encapsulation layer and passive devices.

FIG. 2 illustrates an exemplary cross sectional profile view of a deep trench capacitor device.

FIGS. 3A-3C illustrate an exemplary sequence for fabricating a package that includes integrated devices and an encapsulation layer.

FIG. 4 illustrates an exemplary flow chart of a method for fabricating a package that includes integrated devices, an encapsulation layer and passive devices.

FIG. 5 illustrates an exemplary sequence for fabricating a substrate.

FIG. 6 illustrates an exemplary flow chart of a method for fabricating a substrate.

FIGS. 7A-7C illustrate an exemplary sequence for fabricating a substrate.

FIG. 8 illustrates an exemplary flow chart of a method for fabricating a substrate.

FIGS. 9A-9B illustrate an exemplary sequence for fabricating a metallization portion.

FIG. 10 illustrates an exemplary flow chart of a method for fabricating a metallization portion.

FIG. 11 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a package comprising a substrate; a first integrated device coupled to the substrate through at least a first plurality of solder interconnects; an encapsulation layer at least partially encapsulating the first integrated device, wherein the encapsulation layer includes a cavity; a metallization portion coupled to the first integrated device; and a first passive device coupled to the metallization portion through at least a second plurality of solder interconnects, wherein the first passive device is located at least partially in the cavity of the encapsulation layer. The package provides passive devices that are located very close to integrated devices, which may help improve the performance of the power distribution network of the integrated devices and/or the package. Moreover, the package provides a configuration of a package with a compact form factor that can be implemented and/or integrated into smaller devices.

### Exemplary Package Comprising Integrated Devices and Passive Devices

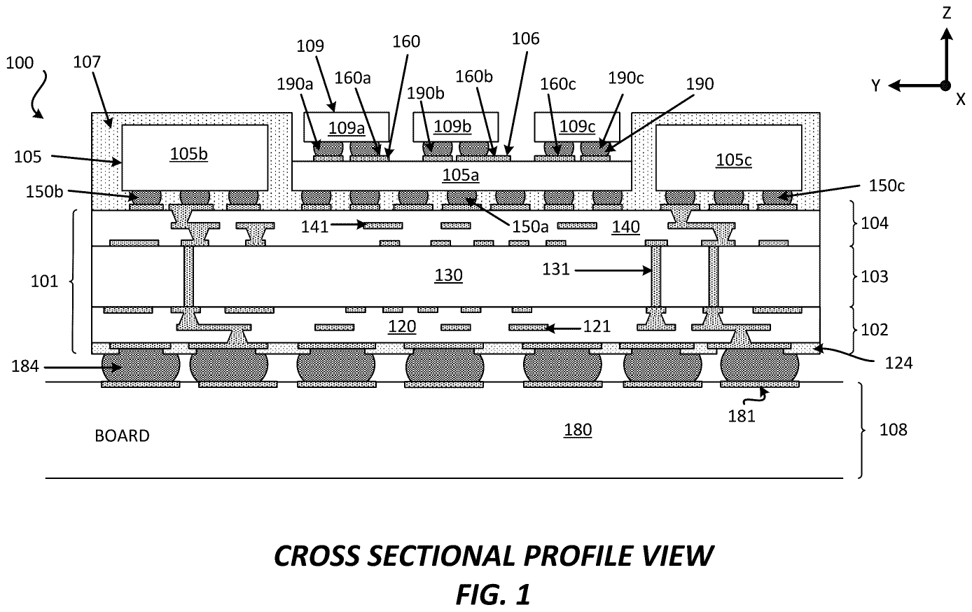

FIG. 1 illustrates a cross sectional profile view of a package 100 that includes integrated devices. The package 100 is coupled to a board 108 through a plurality of solder interconnects 184. The board 108 includes at least one board dielectric layer 180 and a plurality of board interconnects 181. The board 108 may include a printed circuit board (PCB). In some implementations, the package 100 may be coupled to a substrate instead of the board 108.

The package 100 includes a substrate 101, a plurality of integrated devices 105, an encapsulation layer 107, a metallization portion 106 and a plurality of passive devices 109. As will be further described below, the plurality of passive devices 109 may be located in the package 100 in such a way as to be as close as possible to an integrated device, which will help improve the performance of the power distribution network of the integrated devices and/or the package 100.

The substrate 101 includes a metallization portion 102, an interposer portion 103 and a metallization portion 104. In some implementations, the metallization portion 102 may be a first metallization portion and the metallization portion 104 may be a second metallization portion. In some implementations, the metallization portion 104 may be a first metallization portion and the metallization portion 102 may be a second metallization portion. The metallization portion 102 is coupled to the interposer portion 103. The metallization portion 104 is coupled to the interposer portion 103. The interposer portion 103 is located between the metallization portion 102 and the metallization portion 104.

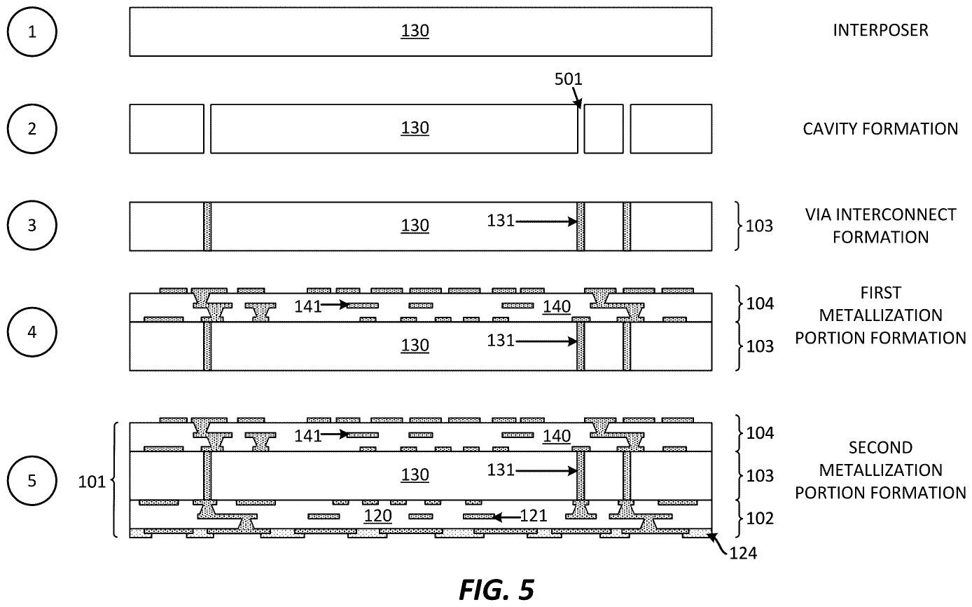

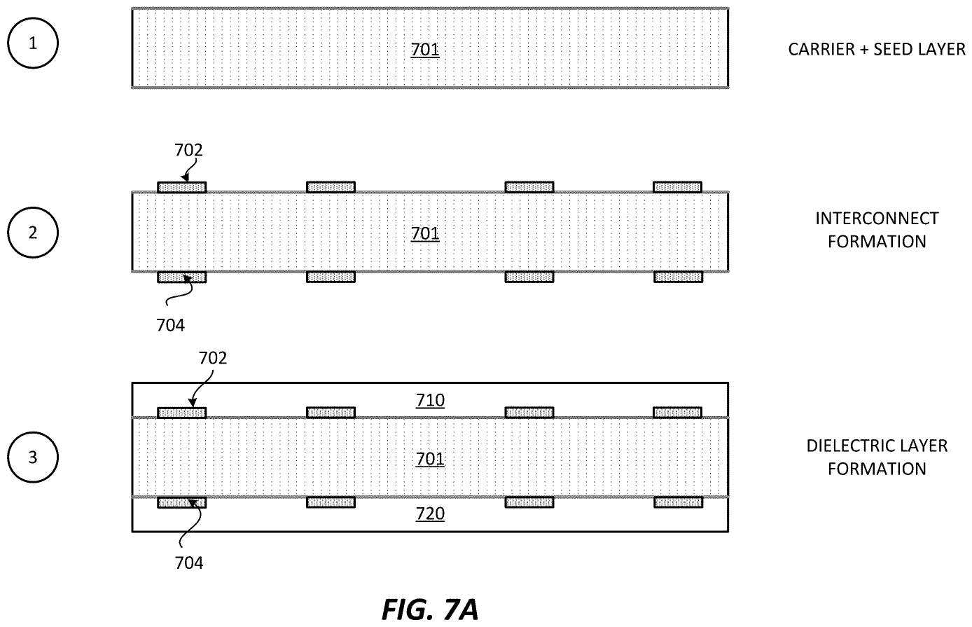

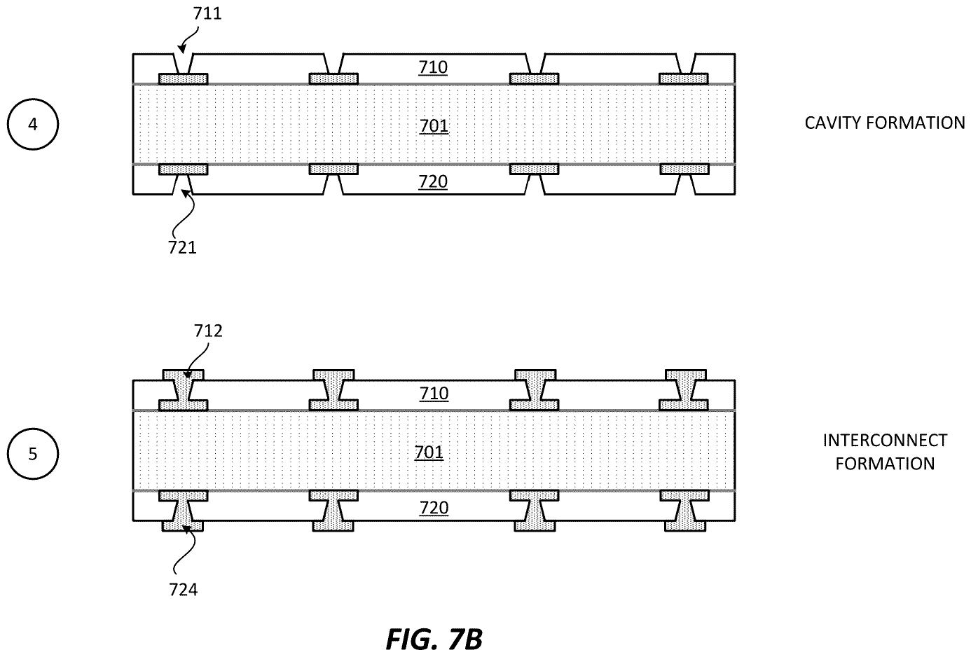

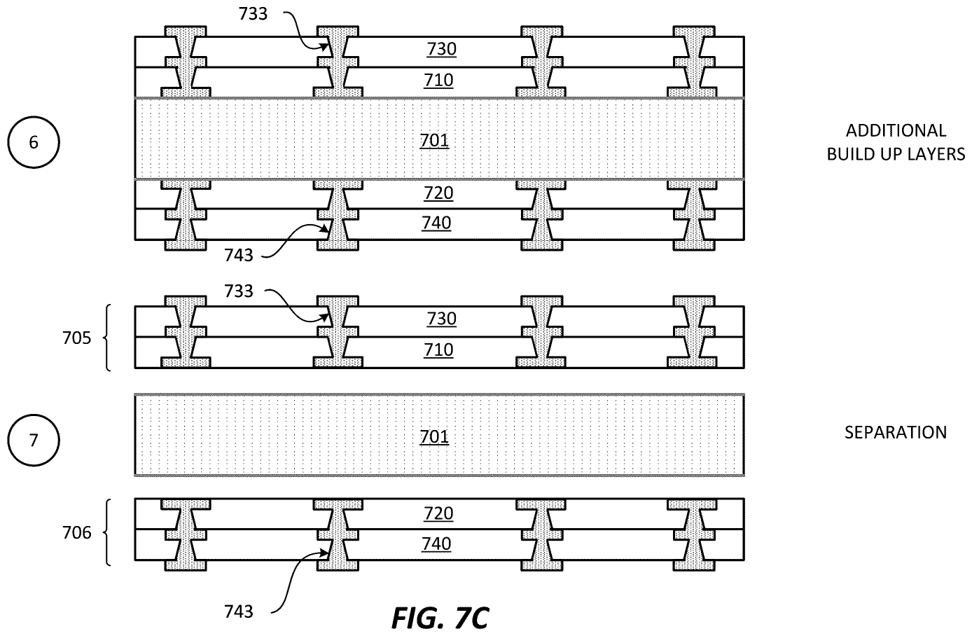

The interposer portion 103 includes an interposer 130 and a plurality of through interposer via interconnects 131. The interposer 130 may include silicon (Si). The interposer 130 may be a type of a dielectric. The metallization portion 102 includes at least one dielectric layer 120, a plurality of metallization interconnects 121 and a solder resist layer 124. In some implementations, the solder resist layer 124 may include a polyimide dielectric layer. The metallization portion 104 includes at least one dielectric layer 140 and a plurality of metallization interconnects 141. The at least one dielectric layer 120 and/or the at least one dielectric layer 140 may be a different material from the interposer 130. In some implementations, the at least one dielectric layer 120 and/or the at least one dielectric layer 140 may include prepreg and/or polyimide. The plurality of through interposer via interconnects 131 are coupled to the plurality of metallization interconnects 121 and the plurality of metallization interconnects 141. An electrical path through the substrate 101 may include (i) at least one metallization interconnect from the plurality of metallization interconnects 121, (ii) at least one through interposer via interconnects from the plurality of through interposer via interconnects, and (iii) at least one metallization interconnect from the plurality of metallization interconnects 141. The use of the substrate 101 that includes a metallization portion 102, an interposer portion 103 and a metallization portion 104, helps provide high density interconnects in a compact package. Different implementations may use different substrates, such as a laminated substrate (e.g., coreless substrate, cored substrate). An example of a process for fabricating the substrate 101 is illustrated and described below in at least FIG. 5. An example of a process for fabricating another substrate is illustrated and described below in at least FIGS. 7A-7C.

The plurality of integrated devices 105 may include an integrated device 105a (e.g., first integrated device), an integrated device 105b (e.g., second integrated device) and an integrated device 105c (e.g., third integrated device). In some implementations, The thickness of the integrated device 105a may be less than a thickness of the integrated device 105b and/or a thickness of the integrated device 105c. The integrated device 105a is located laterally between the integrated device 105b and the integrated device 105c. In some implementations, the integrated device 105a may be a processor device. In some implementations, the integrated device 105b may be a memory device. In some implementations, the integrated device 105c may be a memory device.

The integrated device 105a is coupled to the metallization portion 104 of the substrate 101 through a plurality of solder interconnects 150a (e.g., first plurality of solder interconnects). In some implementations, the integrated device 105a is coupled to the metallization portion 104 of the substrate 101 through a plurality of pillar interconnects (not shown) and the plurality of solder interconnects 150a. The plurality of solder interconnects 150a may be coupled to and touch metallization interconnects from the plurality of metallization interconnects 141.

The integrated device 105b is coupled to the metallization portion 104 of the substrate 101 through a plurality of solder interconnects 150b (e.g., third plurality of solder interconnects). In some implementations, the integrated device 105b is coupled to the metallization portion 104 of the substrate 101 through a plurality of pillar interconnects (not shown) and the plurality of solder interconnects 150b. The plurality of solder interconnects 150b may be coupled to and touch metallization interconnects from the plurality of metallization interconnects 141.

The integrated device 105c is coupled to the metallization portion 104 of the substrate 101 through a plurality of solder interconnects 150c (e.g., fourth plurality of solder interconnects). In some implementations, the integrated device 105c is coupled to the metallization portion 104 of the substrate 101 through a plurality of pillar interconnects (not shown) and the plurality of solder interconnects 150c. The plurality of solder interconnects 150c may be coupled to and touch metallization interconnects from the plurality of metallization interconnects 141.

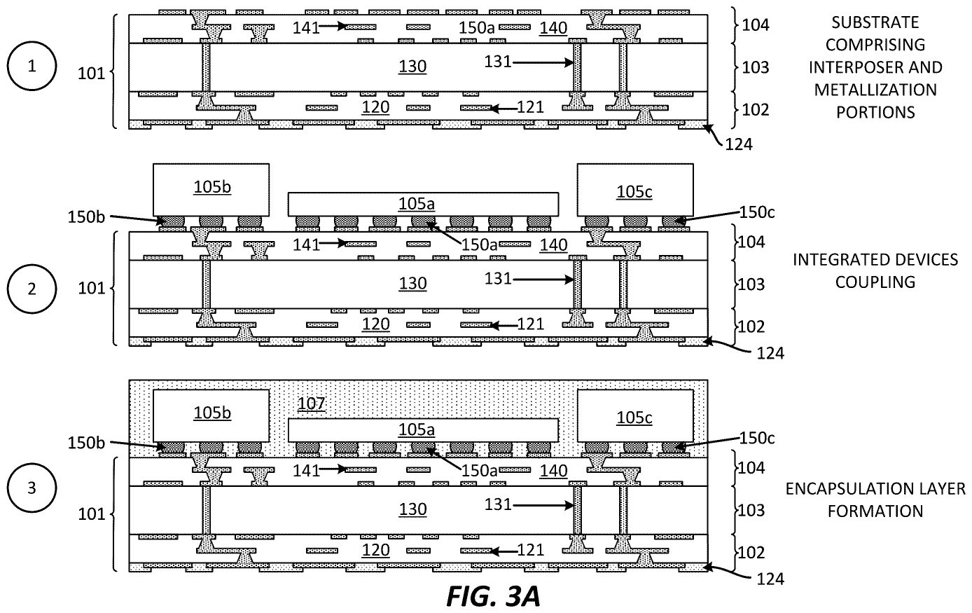

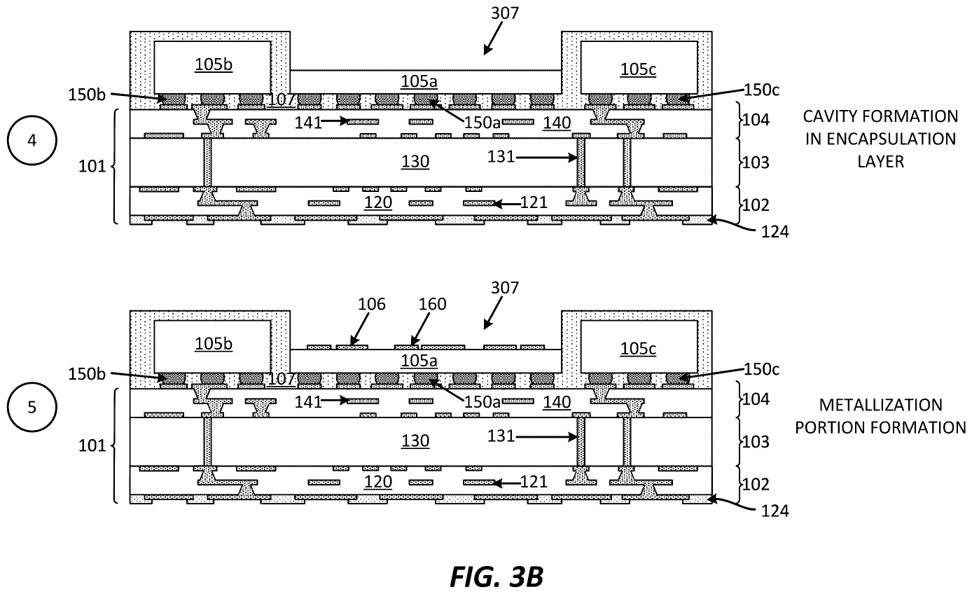

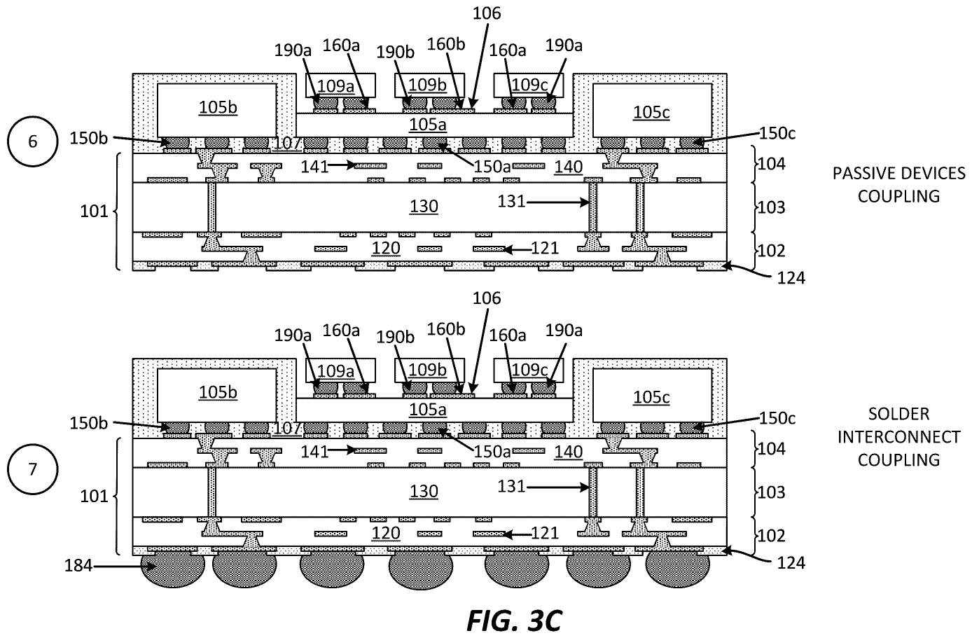

The encapsulation layer 107 is coupled to the substrate 101. For example, the encapsulation layer 107 may be coupled to a surface of the metallization portion 104 of the substrate 101. The encapsulation layer 107 at least partially encapsulates the integrated device 105a, the integrated device 105b, and the integrated device 105c. The encapsulation layer 107 includes a cavity. An example of a cavity of the encapsulation layer 107 is illustrated and described below in at least FIG. 3B. This cavity may be at least partially filled and/or occupied by another material and/or component.

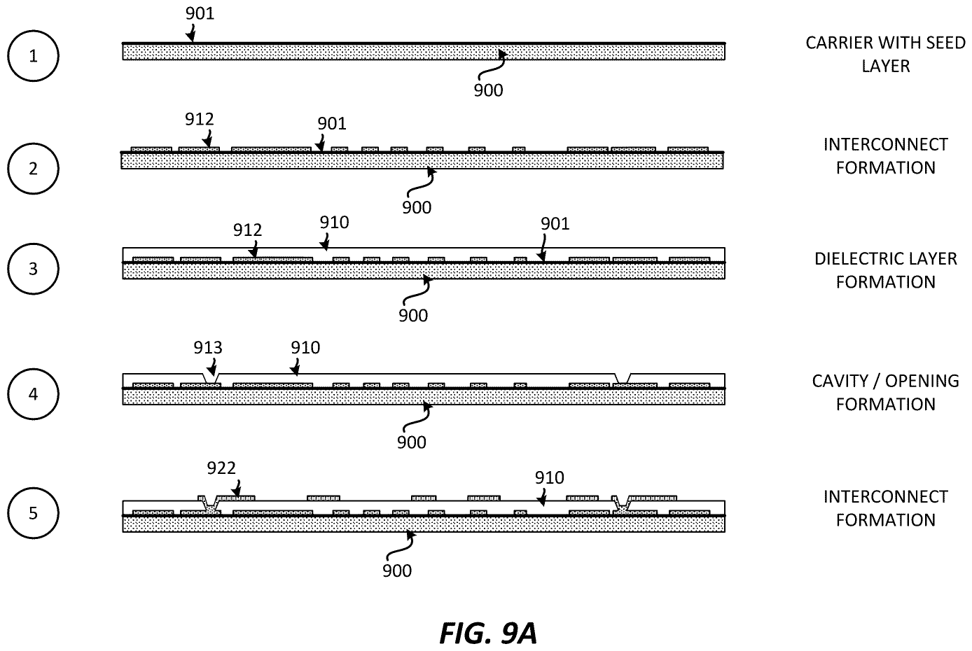

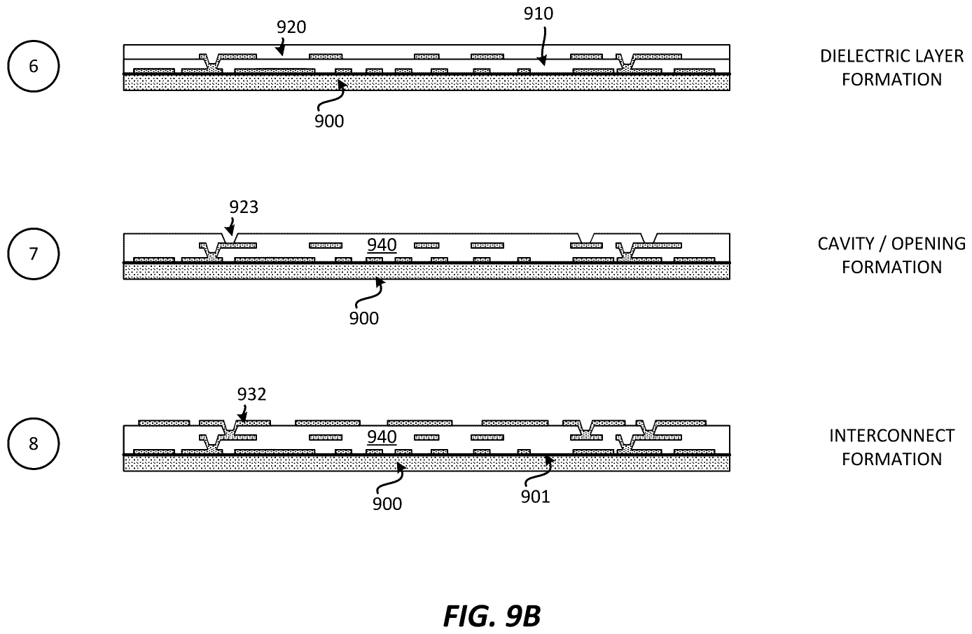

A metallization portion 106 is coupled to a back side of the integrated device 105a. The metallization portion 106 may be located at least partially in the cavity of the encapsulation layer 107. The metallization portion 106 may include one or more metal layers. The metallization portion 106 may include a plurality of metallization interconnects 160. In some implementations, the metallization portion 106 may include at least one dielectric layer. Some of the metallization interconnects from the plurality of metallization interconnects 160 may be configured as one or more inductors. The plurality of metallization interconnects 160 includes a first plurality of metallization interconnects 160a, a second plurality of metallization interconnects 160b and a third plurality of metallization interconnects 160c. The first plurality of metallization interconnects 160a may be configured as a first inductor. The second plurality of metallization interconnects 160b may be configured as a second inductor. The third plurality of metallization interconnects 160c may be configured as a third inductor. An example of fabricating a metallization portion is illustrated and described below in at least FIGS. 9A-9B.

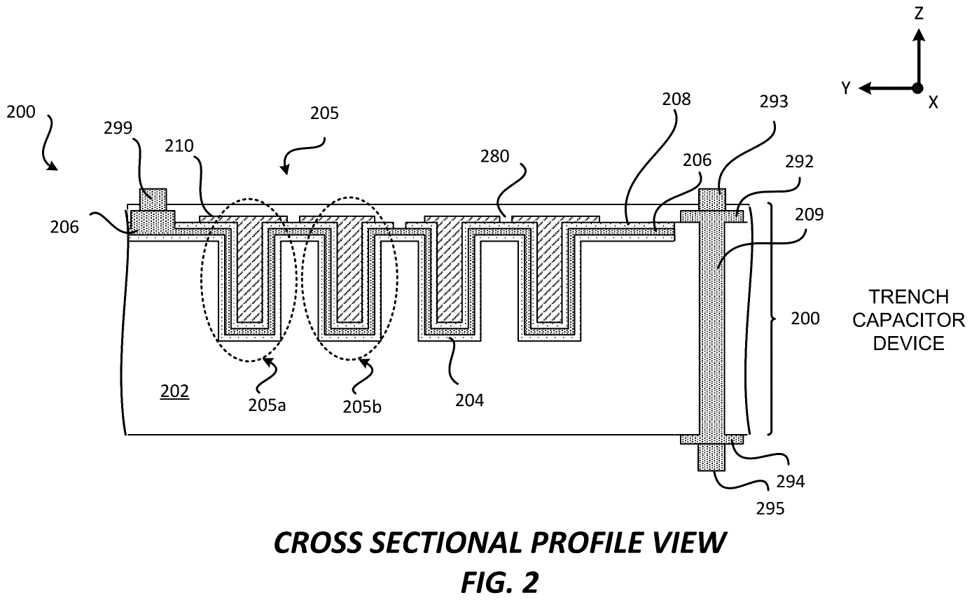

The plurality of passive devices 109 includes a passive device 109a, a passive device 109b and a passive device 109c. The passive device 109a, the passive device 109b and/or the passive device 109c may be a deep trench capacitor device. An example of a deep trench capacitor device is illustrated and described below in FIG. 2.

The plurality of passive devices 109 are located at least partially in the cavity of the encapsulation layer 107. The plurality of passive devices 109 may vertically overlap with the integrated device 105a. The plurality of passive devices 109 may be located laterally to the integrated device 105b and/or the integrated device 105c. The plurality of passive devices 109 may be located laterally to a portion of the encapsulation layer 107. The plurality of passive devices 109 may be surrounded laterally by the encapsulation layer 107. The plurality of passive devices 109 are coupled to the metallization portion 106 through a plurality of solder interconnects 190. The passive device 109a is coupled to the first plurality of metallization interconnects 160a through a plurality of solder interconnects 190a. The passive device 109b is coupled to the second plurality of metallization interconnects 160b through a plurality of solder interconnects 190b. The passive device 109c is coupled to the third plurality of metallization interconnects 160c through a plurality of solder interconnects 190c.

In some implementations, an electrical path between the passive device 109a and the integrated device 105a includes (i) at least one solder interconnect from the plurality of solder interconnects 190a, (ii) at least one metallization interconnect from the first plurality of metallization interconnects 160a, and/or (iv) a back side of the integrated device 105a.

In some implementations, an electrical path between the passive device 109b and the integrated device 105a includes (i) at least one solder interconnect from the plurality of solder interconnects 190b, (ii) at least one metallization interconnect from the second plurality of metallization interconnects 160b, and/or (iv) a back side of the integrated device 105a.

In some implementations, an electrical path between the passive device 109c and the integrated device 105a includes (i) at least one solder interconnect from the plurality of solder interconnects 190c, (ii) at least one metallization interconnect from the third plurality of metallization interconnects 160c, and/or (iv) a back side of the integrated device 105a.

The package 100 provides a plurality of passive devices 109 that are located very close to the integrated device 105a, which may help improve the performance of the power distribution network of the integrated device 105a and/or the package 100. Moreover, the package 100 provides a configuration of a package with a compact form factor that can be implemented and/or integrated into smaller devices.

Different implementations may have different implementations of a package. For example, the package 100 may be implemented with a different configuration of a substrate, such a laminated substrate (e.g., coreless substrate, cored substrate), instead of the substrate 101.

FIG. 2 illustrates a cross sectional profile view of a passive device 200 that is configured as a trench capacitor device. The passive device 200 includes bump interconnects with different sizes. The passive device 200 may be an integrated passive device. The passive device 200 may represent any of the passive devices described in the disclosure. For example, the passive device 200 may represent the passive device(s) 209a, 209b and/or 209c. The passive device 200 may be an integrated passive device (e.g., passive device) that includes multiple trench capacitors (e.g., deep trench capacitors). The passive device 200 may be a means for trench capacitance. The passive device 200 includes a front side and a back side. The front side of the passive device 200 may include the plurality of trench capacitors.

The passive device 200 includes a passive device substrate 202 (e.g., passive device substrate) and a plurality of trench capacitors 205. A plurality of solder interconnects (not shown) may be coupled to the passive device 200. The passive device substrate 202 may include silicon (Si). The passive device substrate 202 may include a plurality of trenches and/or cavities over which capacitors may be formed.

The plurality of trench capacitors 205 includes a trench capacitor 205a and a trench capacitor 205b. In some implementations, the trench capacitor 205a and the trench capacitor 205b may be configured to be part of a same capacitor (e.g., first capacitor, first trench capacitor). In some implementations, the trench capacitor 205a and the trench capacitor 205b may be configured to be coupled to and/or part of a first power distribution network (PDN). The trench capacitor 205a and the trench capacitor 205b may be configured to be part of a first electrical path for a first power for a package. The trench capacitor 205a and the trench capacitor 205b may be configured to be coupled to integrated device(s).

As shown in FIG. 2, the passive device 200 includes the passive device substrate 202, an oxide layer 204, a first electrically conductive layer 206, a dielectric layer 208, a second electrically conductive layer 210 and a dielectric layer 280. The first electrically conductive layer 206 and/or the second electrically conductive layer 210 may include polysilicon. The oxide layer 204 and/or the dielectric layer 208 may include SiO₂ (e.g., low-pressure chemical vapor deposition (LPCVD) SiO₂) or Si₃N₄ (e.g., LPCVD Si₃N₄). Portions of the oxide layer 204, the first electrically conductive layer 206, the dielectric layer 208, and the second electrically conductive layer 210 may be located in trenches and/or cavities of the passive device substrate 202. The dielectric layer 280 may include silicon nitride. It is noted that a passive device substrate 202 may be considered to have a trench or a cavity, even if the trench or the cavity is filled with one or more materials.

The trench capacitor 205a (e.g., first trench capacitor, first capacitor, means for first trench capacitance) may be defined by (i) a first portion of the oxide layer 204, (ii) a first portion of the first electrically conductive layer 206, (iii) a first portion of the dielectric layer 208, and (iv) a first portion of the second electrically conductive layer 210 that are located in a trench (e.g., first trench) of the passive device substrate 202.

The trench capacitor 205b (e.g., second trench capacitor, second capacitor, means for second trench capacitance) may be defined by (i) a second portion of the oxide layer 204, (ii) a second portion of the first electrically conductive layer 206, (iii) a second portion of the dielectric layer 208, and (iv) a second portion of the second electrically conductive layer 210 that are located in a trench (e.g., second trench) of the passive device substrate 202. It is noted that trench capacitor 205b may be part of a same capacitor as the trench capacitor 205a. That is, the trench capacitor 205a and the trench capacitor 205b may be configured to be electrically coupled together to form a capacitor (e.g., first capacitor) with a greater capacitance. The passive device 200 may also optionally include a post interconnect 299 that is coupled to the first electrically conductive layer 206. The passive device may also include other post interconnects that are coupled to other second electrically conductive layer 210.

The passive device 200 also includes an interconnect 209, an interconnect 292, and an interconnect 294. The interconnect 209 is coupled to the interconnect 292 and the interconnect 294. The interconnect 209 may be a through substrate via that extends through the passive device substrate 202. The interconnect 292 may be a pad interconnect. The interconnect 294 may be a pad interconnect. The interconnect 292 may be located on the front side of the passive device 200. The interconnect 294 may be located on the back side of the passive device 200. The interconnect 209 may be a through passive device substrate interconnect. The passive device may include at least one through passive device substrate interconnect. The interconnect 292 may be part of a plurality of metallization interconnects (e.g., plurality of front side metallization interconnects). The interconnect 294 may be part of a plurality of metallization interconnects (e.g., plurality of back side metallization interconnects). The passive device 200 may also optionally include a post interconnect 293 and a post interconnect 295. The post interconnect 293 may be coupled to the interconnect 292. The post interconnect 295 may be coupled to the interconnect 294. In some implementations, the post interconnect 295 may include copper. In some implementations, the post interconnect 295 may include a copper layer, a nickel layer and another copper layer. The post interconnect 295 may be part of a plurality of post interconnects. The post interconnect 299 may be part of a plurality of post interconnects. The post interconnect 293 may be part of a plurality of post interconnects. A plurality of solder interconnects may be coupled to the post interconnect 293, the post interconnect 295 and/or the post interconnect 299.

As mentioned above, the passive device 200 includes a plurality of bump interconnects. The plurality of bump interconnects for the passive device 200 may include the post interconnect 293, the post interconnect 295 and/or the post interconnect 299. In some implementations, the plurality of bump interconnects for the passive device 200 may include the solder interconnects that may be coupled to the post interconnect 293, the post interconnect 295, and/or the post interconnect 299.

The passive device 200 may include a plurality of front side bump interconnects and/or a plurality of back side bump interconnects. In some implementations, the post interconnect 299 and/or the post interconnect 293 may be part of a plurality of front side bump interconnects. In some implementations, the post interconnect 295 may be part of a plurality of back side bump interconnects. The plurality of bump interconnects may have different sizes, shapes and/or heights. For example, the plurality of bump interconnects may include bump interconnects with different widths and/or minimum widths. A plurality of bump interconnects with varying sizes and/or varying widths are further illustrated and described below in FIG. 2.

An integrated device (e.g., 105a) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 105a) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap width between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100) may be implemented in a radio frequency (RF) package. The RF package may be a radio frequency front end (RFFE) package. A package (e.g., 100) may be configured to provide Wireless Fidelity (WiFi) communication and/or cellular communication (e.g., 2G, 3G, 4G, 5G, 6G). The packages (e.g., 100) may be configured to support Global System for Mobile (GSM) Communications, Universal Mobile Telecommunications System (UMTS), and/or Long-Term Evolution (LTE). The packages (e.g., 100) may be configured to transmit and receive signals having different frequencies and/or communication protocols.

### Exemplary Sequence for Fabricating a Package Comprising Integrated Devices and Passive Devices

In some implementations, fabricating a package includes several processes. FIGS. 3A-3C illustrate an exemplary sequence for providing or fabricating a package. In some implementations, the sequence of FIGS. 3A-3C may be used to provide or fabricate the package 100. However, the process of FIGS. 3A-3C may be used to fabricate any of the packages described in the disclosure.

It should be noted that the sequence of FIGS. 3A-3C may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 3A, illustrates a state after a substrate 101 is provided and/or fabricated. The substrate 101 includes an interposer portion 103, a metallization portion 102 and a metallization portion 104. The interposer portion 103 includes an interposer 130 and a plurality of through interposer via interconnects 131. The interposer 130 may include silicon (Si). The interposer 130 may be a type of a dielectric. The metallization portion 102 includes at least one dielectric layer 120, a plurality of metallization interconnects 121 and a solder resist layer 124. In some implementations, the solder resist layer 124 may include a polyimide dielectric layer. The metallization portion 104 includes at least one dielectric layer 140 and a plurality of metallization interconnects 141. FIG. 5 illustrates and describes an example of fabricating the substrate 101. In some implementations, other substrates may be used. An example of a process for fabricating another substrate is illustrated and described below in at least FIGS. 7A-7C.

Stage 2 illustrates a state after the plurality of integrated devices 105 are coupled to the substrate 101. The integrated device 105a may be coupled to metallization interconnects from the plurality of metallization interconnects 141 through a plurality of solder interconnects 150a. The integrated device 105b may be coupled to metallization interconnects from the plurality of metallization interconnects 141 through a plurality of solder interconnects 150b. The integrated device 105c may be coupled to metallization interconnects from the plurality of metallization interconnects 141 through a plurality of solder interconnects 150c. A solder reflow process may be used to couple the plurality of integrated devices 105 to the metallization portion 104 through the plurality of solder interconnects 150.

Stage 3 illustrates a state after an encapsulation layer 107 is provided and formed. The encapsulation layer 107 may include a mold, a resin, an epoxy and/or a filler. The encapsulation layer 107 may be provided by using a compression and transfer molding process, a sheet molding process, or a liquid molding process. The encapsulation layer 107 may be coupled to the substrate 101. The encapsulation layer 107 may at least partially encapsulate the integrated device 105a, the integrated device 105b and the integrated device 105c. In some implementations, forming the encapsulation layer may include planarizing the encapsulation layer 107, which may include removing portions of the encapsulation layer 107. Planarizing the encapsulation layer 107 may include removing back side portions of the integrated device 105a.

Stage 4, as shown in FIG. 3B, illustrates a state after a cavity 307 is formed in the encapsulation layer 107. The cavity 307 may be located vertically over the back side of the integrated device 105a and located laterally at least part of the integrated device 105b and/or at least part of the integrated device 105c. The cavity 307 may expose the back side of the integrated device 105a. Different implementations may form the cavity 307 differently. An etching process, a polishing process and/or a grinding process may be used to form the cavity 307 in the encapsulation layer 107.

Stage 5 illustrates a state after a metallization portion 106 is provided and/or formed over a surface of the back side of the integrated device 105a. The metallization portion 106 may be provided in the cavity 307 of the encapsulation layer 107. The metallization portion 106 may include a plurality of metallization interconnects 160. Some of the metallization interconnects from the plurality of metallization interconnects 160 may be configured as one or more inductors. The metallization portion 106 may include one or more metal layers. The metallization portion 106 may include at least one dielectric layer. FIGS. 9A-9B illustrate and describe an example of fabricating a metallization portion.

Stage 6, as shown in FIG. 3C, illustrates a state after a plurality of passive devices 109 are placed in the cavity 307 of the encapsulation layer 107 and coupled to the metallization portion 106. A solder reflow process may be used to couple the plurality of passive devices 109 to the plurality of metallization interconnects 160 through the plurality a plurality of solder interconnects 190. The plurality of passive devices 109 may be located partially or entirely in the cavity 307 of the encapsulation layer 107.

The passive device 109a may be coupled to the first plurality of metallization interconnects 160a through a plurality of solder interconnects 190a. The passive device 109b may be coupled to the first plurality of metallization interconnects 160b through a plurality of solder interconnects 190b. The passive device 109c may be coupled to the first plurality of metallization interconnects 160c through a plurality of solder interconnects 190c.

Stage 7 illustrates a state after a plurality of solder interconnects 184 are coupled to the substrate 101. A solder reflow process may be used to couple the plurality of solder interconnects 184 to the plurality of metallization interconnects 121 of the metallization portion 102 of the substrate 101. Stage 7 may illustrate an example of a package 100.

### Exemplary Flow Diagram of a Method for Fabricating a Package Comprising Integrated Devices and Passive Devices

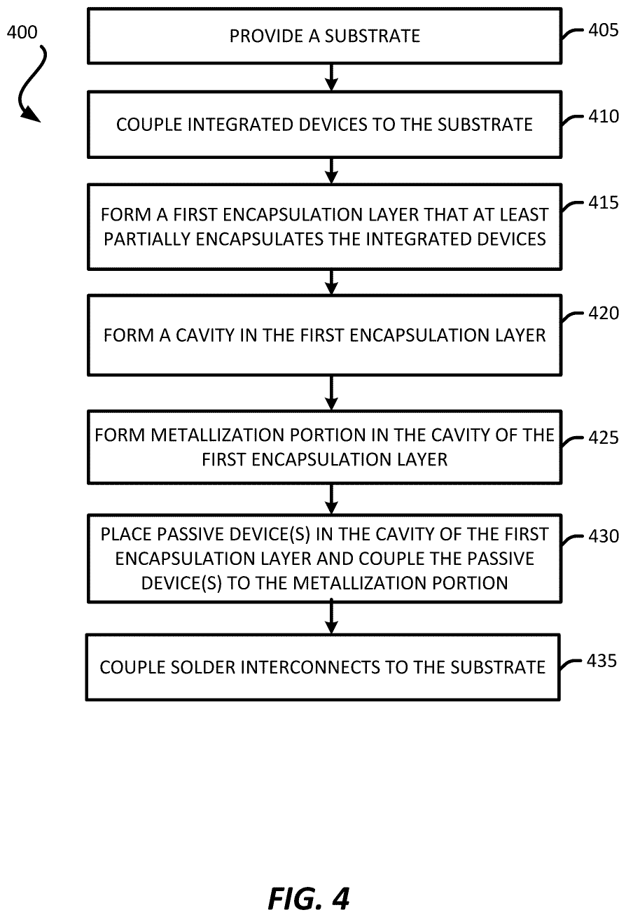

In some implementations, fabricating a package includes several processes. FIG. 4 illustrates an exemplary flow diagram of a method 400 for providing or fabricating a package. In some implementations, the method 400 of FIG. 4 may be used to provide or fabricate the package 100 described in the disclosure. However, the method 400 may be used to provide or fabricate any of the packages described in the disclosure.

It should be noted that the method 400 of FIG. 4 may combine one or more processes in order to simplify and/or clarify the method for providing or fabricating a package. In some implementations, the order of the processes may be changed or modified.

The method provides (at 405) a substrate. The substrate may include an interposer and metallization portions. Stage 1 of FIG. 3A, illustrates and describes an example of a state after a substrate 101 is provided and/or fabricated. The substrate 101 includes an interposer portion 103, a metallization portion 102 and a metallization portion 104. The interposer portion 103 includes an interposer 130 and a plurality of through interposer via interconnects 131. The interposer 130 may include silicon (Si). The interposer 130 may be a type of a dielectric. The metallization portion 102 includes at least one dielectric layer 120, a plurality of metallization interconnects 121 and a solder resist layer 124. In some implementations, the solder resist layer 124 may include a polyimide dielectric layer. The metallization portion 104 includes at least one dielectric layer 140 and a plurality of metallization interconnects 141. FIG. 5 illustrates and describes an example of fabricating the substrate 101. In some implementations, other substrates may be used. An example of a process for fabricating another substrate is illustrated and described below in at least FIGS. 7A-7C.

The method couples (at 410) to the substrate. Stage 2 of FIG. 3A, illustrates and describes an example of a state after the plurality of integrated devices 105 are coupled to the substrate 101. The integrated device 105a may be coupled to metallization interconnects from the plurality of metallization interconnects 141 through a plurality of solder interconnects 150a. The integrated device 105b may be coupled to metallization interconnects from the plurality of metallization interconnects 141 through a plurality of solder interconnects 150b. The integrated device 105c may be coupled to metallization interconnects from the plurality of metallization interconnects 141 through a plurality of solder interconnects 150c. A solder reflow process may be used to couple the plurality of integrated devices 105 to the metallization portion 104 through the plurality of solder interconnects 150.

The method forms (at 415) an encapsulation layer that at least partially the plurality of integrated devices. Stage 3 of FIG. 3A, illustrates and describes an example of a state after an encapsulation layer 107 is provided and formed. The encapsulation layer 107 may include a mold, a resin, an epoxy and/or a filler. The encapsulation layer 107 may be provided by using a compression and transfer molding process, a sheet molding process, or a liquid molding process. The encapsulation layer 107 may be coupled to the substrate 101. The encapsulation layer 107 may at least partially encapsulate the integrated device 105a, the integrated device 105b and the integrated device 105c. In some implementations, forming the encapsulation layer may include planarizing the encapsulation layer 107, which may include removing portions of the encapsulation layer 107. Planarizing the encapsulation layer 107 may include removing back side portions of the integrated device 105a.

The method forms (at 420) a cavity in the encapsulation layer. Stage 4 of FIG. 3B, illustrates and describes an example of a state after a cavity 307 is formed in the encapsulation layer 107. The cavity 307 may be located vertically over the back side of the integrated device 105a and located laterally at least part of the integrated device 105b and/or at least part of the integrated device 105c. The cavity 307 may expose the back side of the integrated device 105a. Different implementations may form the cavity 307 differently. An etching process, a polishing process and/or a grinding process may be used to form the cavity 307 in the encapsulation layer 107.

The method forms (at 425) a metallization portion on the back side of the integrated device. Stage 5 of FIG. 3B, illustrates and describes an example of a state after a metallization portion 106 is provided and/or formed over a surface of the back side of the integrated device 105a. The metallization portion 106 may be provided in the cavity 307 of the encapsulation layer 107. The metallization portion 106 may include a plurality of metallization interconnects 160. Some of the metallization interconnects from the plurality of metallization interconnects 160 may be configured as one or more inductors. The metallization portion 106 may include one or more metal layers. The metallization portion 106 may include at least one dielectric layer. FIGS. 9A-9B illustrate and describe an example of fabricating a metallization portion.

The method places (at 430) a plurality of passive devices in the cavity of the encapsulation layer and couples (at 430) to the metallization portion. Stage 6 of FIG. 3C, illustrates and describes an example of a state after a plurality of passive devices 109 are placed in the cavity 307 of the encapsulation layer 107 and coupled to the metallization portion 106. A solder reflow process may be used to couple the plurality of passive devices 109 to the plurality of metallization interconnects 160 through the plurality a plurality of solder interconnects 190. The plurality of passive devices 109 may be located partially or entirely in the cavity 307 of the encapsulation layer 107.

The passive device 109a may be coupled to the first plurality of metallization interconnects 160a through a plurality of solder interconnects 190a. The passive device 109b may be coupled to the first plurality of metallization interconnects 160b through a plurality of solder interconnects 190b. The passive device 109c may be coupled to the first plurality of metallization interconnects 160c through a plurality of solder interconnects 190c.

The method couples (at 435) a plurality of solder interconnects to the substrate. Stage 7 of FIG. 3C, illustrates and describes an example of a state after a plurality of solder interconnects 184 are coupled to the substrate 101. A solder reflow process may be used to couple the plurality of solder interconnects 184 to the plurality of metallization interconnects 121 of the metallization portion 102 of the substrate 101. Stage 7 may illustrate an example of a package 100.

### Exemplary Sequence for Fabricating a Substrate

In some implementations, fabricating a substrate includes several processes. FIG. 5 illustrates an exemplary sequence for providing or fabricating a substrate. In some implementations, the sequence of FIG. 5 may be used to provide or fabricate the substrate 101. However, the process of FIG. 5 may be used to fabricate any substrates.

It should be noted that the sequence of FIG. 5 may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 5, illustrates a state after an interposer 130 is provided. The interposer 130 may include silicon (Si). Different implementations may use different materials for the interposer 130. In some implementations, the interposer 130 may include seed layers (not shown) that are located one or more surfaces of the interposer 130.

Stage 2 illustrates a state after a plurality of cavities 501 are formed in the interposer 130. An etching process and/or a drilling process may be used to form the plurality of cavities 501 in the interposer 130.

Stage 3 illustrates a state after a plurality of through interposer via interconnects 131 are formed in the plurality of cavities 501 of the interposer 130. A plating process may be used to form the plurality of through interposer via interconnects 131. Stage 3 may illustrates an interposer portion 103.

Stage 4 illustrates a state after a metallization portion 104 is formed and coupled to the interposer portion 103. In some implementations, the metallization portion 104 may be a first metallization portion. The metallization portion 104 may include at least one dielectric layer 140 and a plurality of metallization interconnects 141. FIGS. 9A-9B illustrates an example of a process for fabricating a metallization portion.

Stage 5 illustrates a state after a metallization portion 102 is formed and coupled to the interposer portion 103. In some implementations, the metallization portion 102 may be a second metallization portion. The metallization portion 104 may include at least one dielectric layer 120, a plurality of metallization interconnects 121 and a solder resist layer 124. In some implementations, the solder resist layer 124 may include a polyimide dielectric layer. FIGS. 9A-9B illustrate an example of a process for fabricating a metallization portion. In some implementations, the metallization portion 102 is a first metallization portion and the metallization portion 104 is a second metallization. Stage 5 may illustrate an example of a substrate 101 that includes a metallization portion 102, an interposer portion 103 and a metallization portion 104.

### Exemplary Flow Diagram of a Method for Fabricating a Substrate

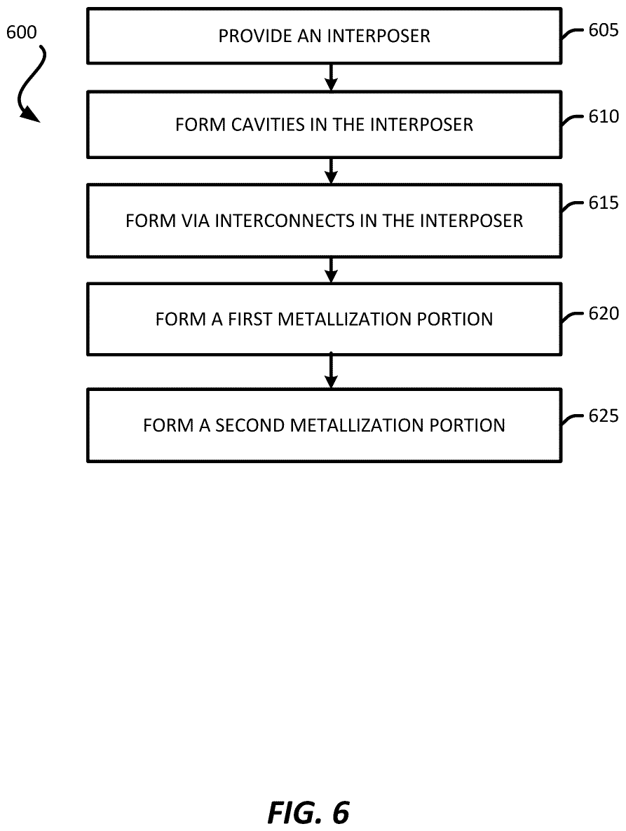

In some implementations, fabricating a substrate includes several processes. FIG. 6 illustrates an exemplary flow diagram of a method 600 for providing or fabricating a substrate. In some implementations, the method 600 of FIG. 6 may be used to provide or fabricate the substrate 101 described in the disclosure. However, the method 600 may be used to provide or fabricate any of the packages described in the disclosure.

It should be noted that the method 600 of FIG. 6 may combine one or more processes in order to simplify and/or clarify the method for providing or fabricating a substrate. In some implementations, the order of the processes may be changed or modified.

The method provides (at 605) an interposer. Stage 1 of FIG. 5, illustrates and describes an example of a state after an interposer 130 is provided. The interposer 130 may include silicon (Si). Different implementations may use different materials for the interposer 130. In some implementations, the interposer 130 may include seed layers (not shown) that are located on surfaces of the interposer 130.

The method forms (at 610) a plurality of cavities in the interposer. Stage 2 of FIG. 5, illustrates and describes an example of a state after a plurality of cavities 501 are formed in the interposer 130. An etching process and/or a drilling process may be used to form the plurality of cavities 501 in the interposer 130.

The method forms (at 615) a plurality of through interposer via interconnects in the interposer. Stage 3 of FIG. 5, illustrates and describes an example of a state after a plurality of through interposer via interconnects 131 are formed in the plurality of cavities 501 of the interposer 130. A plating process may be used to form the plurality of through interposer via interconnects 131. Stage 3 may illustrates an interposer portion 103.

The method forms (at 620) a first metallization portion that is coupled to the interposer portion. Stage 4 of FIG. 5, illustrates and describes an example of a state after a metallization portion 104 is formed and coupled to the interposer portion 103. In some implementations, the metallization portion 104 may be a first metallization portion. The metallization portion 104 may include at least one dielectric layer 140 and a plurality of metallization interconnects 141. FIGS. 9A-9B illustrates an example of a process for fabricating a metallization portion.

The method forms (at 625) a second metallization portion that is coupled to the interposer portion. Stage 5 of FIG. 5, illustrates and describes an example of a state after a metallization portion 102 is formed and coupled to the interposer portion 103. In some implementations, the metallization portion 102 may be a second metallization portion. The metallization portion 104 may include at least one dielectric layer 120, a plurality of metallization interconnects 121 and a solder resist layer 124. In some implementations, the solder resist layer 124 may include a polyimide dielectric layer. FIGS. 9A-9B illustrates an example of a process for fabricating a metallization portion. In some implementations, the metallization portion 102 is a first metallization portion and the metallization portion 104 is a second metallization. Stage 5 may illustrate an example of a substrate 101 that includes a metallization portion 102, an interposer portion 103 and a metallization portion 104.

### Exemplary Sequence for Fabricating a Substrate

In some implementations, fabricating a substrate includes several processes. FIGS. 7A-7C illustrate an exemplary sequence for providing or fabricating a substrate. In some implementations, the sequence of FIGS. 7A-7C may be used to provide or fabricate a laminated substrate. For example, the sequence of FIGS. 7A-7C may be used to provide or fabricate a laminated substrate.

It should be noted that the sequence of FIGS. 7A-7C may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 7A, illustrates a state after a carrier 701 is provided. The carrier 701 may include a core layer. The core layer may include seed layers on surfaces of the core layer.

Stage 2 illustrates a state after a plurality of interconnects 702 and a plurality of interconnects 704 are formed. The plurality of interconnects 702 may be coupled to a first surface (e.g., top surface) of the carrier 701. The plurality of interconnects 704 may be coupled to a second surface (e.g., bottom surface) of the carrier 701. A plating process may be used to form the plurality of interconnects 702 and the plurality of interconnects 704. The plurality of interconnects 702 may be formed on a first seed layer of the carrier 701. The plurality of interconnects 704 may be formed on a second seed layer of the carrier 701.

Stage 3 illustrates a state after a dielectric layer 710 and a dielectric layer 720 are provided. The dielectric layer 710 may be coupled to the first surface of the carrier 701. The dielectric layer 720 may be coupled to the second surface of the carrier 701. A deposition and/or a lamination process may be used to form the dielectric layer 710 and/or the dielectric layer 720. The dielectric layer 710 and/or the dielectric layer 720 may include prepreg, polymer and/or Ajinomoto Build-up Film (ABF).

Stage 4 of FIG. 7B, illustrates a state after a plurality of cavities 711 are formed in the dielectric layer 710, and a plurality of cavities 721 are formed in the dielectric layer 720. An exposure and development process may be used to form the plurality of cavities 711 in the dielectric layer 710 and the plurality of cavities 721 in the dielectric layer 720. Different implementations may use different processes to form the plurality of cavities.

Stage 5 illustrates a state after a plurality of interconnects 712 are formed in the dielectric layer 710, and a plurality of interconnects 724 are formed in the dielectric layer 720. The plurality of interconnects 712 may be coupled to the plurality of interconnects 702. The plurality of interconnects 724 may be coupled to the plurality of interconnects 704. A plating process may be used to form the plurality of interconnects 712 and/or the plurality of interconnects 724.

Stage 6, as shown in FIG. 7C, illustrates a state after additional build up layers are formed. For example, stage 6 illustrates a state after additional dielectric layers and additional interconnects are formed. For example, a dielectric layer 730 may be formed and coupled to the dielectric layer 710. A dielectric layer 740 may be formed and coupled to the dielectric layer 720. A lamination process and/or a deposition process may be used to form the dielectric layer 730 and the dielectric layer 740.

Stage 6 further illustrates a state after a plurality of interconnects 733 are formed in and over the dielectric layer 730, and after a plurality of interconnects 743 are formed in and over the dielectric layer 740. The plurality of 733 may be coupled to the plurality of interconnects 712. The plurality of 743 may be coupled to the plurality of interconnects 724. A plurality of cavities may be formed in the dielectric layer 730 and the dielectric layer 740 in a similar manner as described for forming a plurality of cavities in Stage 4 of FIG. 7B. The plurality of interconnects 733 and the plurality of interconnects 743 may be formed in a similar manner as described for fabricating a plurality of interconnects in Stage 5 of FIG. 7B.

Stage 7 illustrates a state after separation of the dielectric layers from the carrier 701. For example, the dielectric layer 710, the dielectric layer 730, the plurality of interconnects 702, the plurality of interconnects 712 and the plurality of interconnects 733 are separated from the carrier 701 to form a substrate 705 (e.g., coreless substrate). In another example, the dielectric layer 720, the dielectric layer 740, the plurality of interconnects 704, the plurality of interconnects 724 and the plurality of interconnects 743 are separated from the carrier 701 to form a substrate 706 (e.g., coreless substrate).

The substrate 705 and/or the substrate 706 may be used instead of the substrate 101, in the package 100. In some implementations, once separation occurs, one or more solder resist layers may be formed on surface(s) of the substrate 705 and/or the substrate 706. In some implementations, the solder resist layer may include a polyimide dielectric layer

### Exemplary Flow Diagram of a Method for Fabricating a Substrate

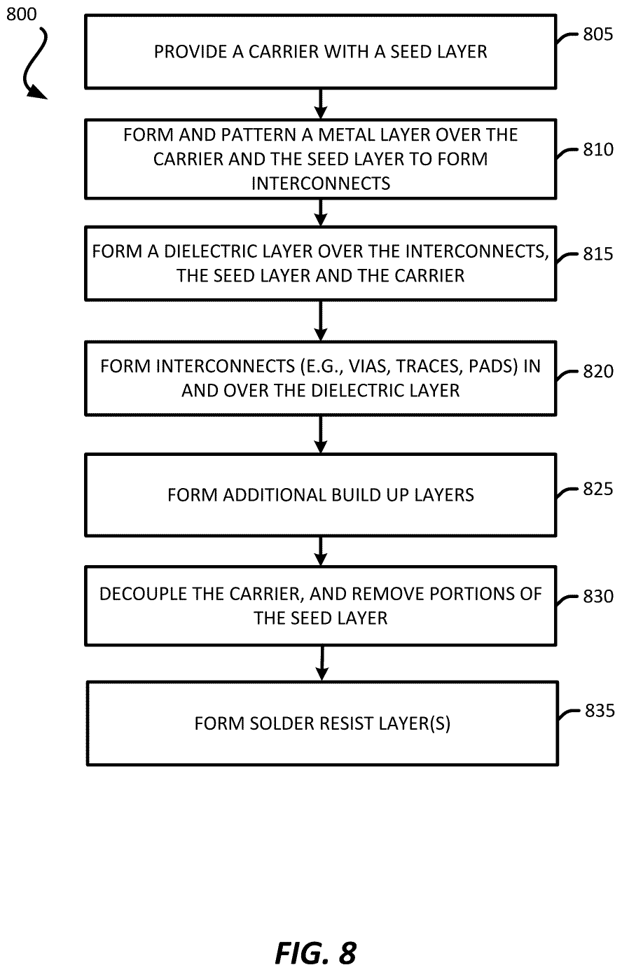

In some implementations, fabricating an substrate includes several processes. FIG. 8 illustrates an exemplary flow diagram of a method 800 for providing or fabricating a substrate. In some implementations, the method 800 of FIG. 8 may be used to provide or fabricate a laminated substrate.

It should be noted that the method 800 of FIG. 8 may combine one or more processes in order to simplify and/or clarify the method for providing or fabricating a substrate. In some implementations, the order of the processes may be changed or modified.

The method provides (at 805) a carrier. The carrier may include seed layers. Stage 1 of FIG. 7A, illustrates and describes an example of a state after a carrier 701 is provided. The carrier 701 may include a core layer. The core layer may include seed layers on surfaces of the core layer.

The method forms (at 810) a plurality of interconnects on the carrier and/or the seed layer(s). Stage 2 of FIG. 7A, illustrates and describes an example of a state after a plurality of interconnects 702 and a plurality of interconnects 704 are formed. The plurality of interconnects 702 may be coupled to a first surface (e.g., top surface) of the carrier 701. The plurality of interconnects 704 may be coupled to a second surface (e.g., bottom surface) of the carrier 701. A plating process may be used to form the plurality of interconnects 702 and the plurality of interconnects 704. The plurality of interconnects 702 may be formed on a first seed layer of the carrier 701. The plurality of interconnects 704 may be formed on a second seed layer of the carrier 701.

The method forms (at 815) at least one dielectric layer over the plurality of interconnects, the seed layer(s) and/or the carrier. Stage 3 of FIG. 7A, illustrates and describes an example of a state after a dielectric layer 710 and a dielectric layer 720 are provided. The dielectric layer 710 may be coupled to the first surface of the carrier 701. The dielectric layer 720 may be coupled to the second surface of the carrier 701. A deposition and/or a lamination process may be used to form the dielectric layer 710 and/or the dielectric layer 720. The dielectric layer 710 and/or the dielectric layer 720 may include prepreg, polymer and/or Ajinomoto Build-up Film (ABF).

Forming the plurality of interconnects may include forming a plurality of cavities in the dielectric layer(s). Stage 4 of FIG. 7B, illustrates and describes an example of a state after a plurality of cavities 711 are formed in the dielectric layer 710, and a plurality of cavities 721 are formed in the dielectric layer 720. An exposure and development process may be used to form the plurality of cavities 711 in the dielectric layer 710 and the plurality of cavities 721 in the dielectric layer 720. Different implementations may use different processes to form the plurality of cavities.

Stage 5 of FIG. 7B, illustrates and describes an example of a state after a plurality of interconnects 712 are formed in the dielectric layer 710, and a plurality of interconnects 724 are formed in the dielectric layer 720. The plurality of interconnects 712 may be coupled to the plurality of interconnects 702. The plurality of interconnects 724 may be coupled to the plurality of interconnects 704. A plating process may be used to form the plurality of interconnects 712 and/or the plurality of interconnects 724.

The method forms (at 825) additional build up layers. Stage 6 of FIG. 7C, illustrates and describes an example of a state after additional build up layers are formed. For example, stage 6 illustrates a state after additional dielectric layers and additional interconnects are formed. For example, a dielectric layer 730 may be formed and coupled to the dielectric layer 710. A dielectric layer 740 may be formed and coupled to the dielectric layer 720. A lamination process and/or a deposition process may be used to form the dielectric layer 730 and the dielectric layer 740.

Stage 6 of FIG. 7C, further illustrates and describes an example of a state after a plurality of interconnects 733 are formed in and over the dielectric layer 730, and after a plurality of interconnects 743 are formed in and over the dielectric layer 740. The plurality of 733 may be coupled to the plurality of interconnects 712. The plurality of 743 may be coupled to the plurality of interconnects 724. A plurality of cavities may be formed in the dielectric layer 730 and the dielectric layer 740 in a similar manner as described for forming a plurality of cavities in Stage 4 of FIG. 7B. The plurality of interconnects 733 and the plurality of interconnects 743 may be formed in a similar manner as described for fabricating a plurality of interconnects in Stage 5 of FIG. 7B.

The method decouples (at 830) the carrier from the dielectric layers. The method may further remove portions of the seed layer(s). Stage 7 of FIG. 7C, illustrates and describes an example of a state after separation of the dielectric layers from the carrier 701. For example, the dielectric layer 710, the dielectric layer 730, the plurality of interconnects 702, the plurality of interconnects 712 and the plurality of interconnects 733 are separated from the carrier 701 to form a substrate 705 (e.g., coreless substrate). In another example, the dielectric layer 720, the dielectric layer 740, the plurality of interconnects 704, the plurality of interconnects 724 and the plurality of interconnects 743 are separated from the carrier 701 to form a substrate 706 (e.g., coreless substrate). The substrate 705 and/or the substrate 706 may be used instead of the substrate 101, in the package 100.

The method may further form (at 835) solder resist layer(s) on the substrate. In some implementations, once separation occurs, one or more solder resist layers may be formed on surface(s) of the substrate 705 and/or the substrate 706. In some implementations, the solder resist layer may include a polyimide dielectric layer

### Exemplary Sequence for Fabricating a Metallization Portion

In some implementations, fabricating a metallization portion includes several processes. FIGS. 9A-9B illustrate an exemplary sequence for providing or fabricating a metallization portion. In some implementations, the sequence of FIGS. 9A-9B may be used to provide or fabricate the metallization portion 102, the metallization portion 104 and/or the metallization portion 106. However, the process of FIGS. 9A-9B may be used to fabricate any of the metallization portions described in the disclosure.

It should be noted that the sequence of FIGS. 9A-9B may combine one or more stages in order to simplify and/or clarify the sequence for providing or fabricating a metallization portion. In some implementations, the order of the processes may be changed or modified. In some implementations, one or more of processes may be replaced or substituted without departing from the scope of the disclosure.

Stage 1, as shown in FIG. 9A, illustrates a state after a carrier 900 is provided. A seed layer 901 may be located over the carrier 900. The carrier 900 may be replaced with other components and/or materials.

Stage 2 illustrates a state after a plurality of interconnects 912 are formed. The interconnects 912 may be located over the seed layer 901. A lithography process, a plating process, a strip process and/or an etching process may be used to form the plurality of interconnects 912. The interconnects 912 may represent at least some of the interconnects from the plurality of metallization interconnects 121.

Stage 3 illustrates a state after a dielectric layer 910 is formed over the carrier 900, the seed layer 901 and the plurality of interconnects 912. A deposition and/or lamination process may be used to form the dielectric layer 910. The dielectric layer 910 may include prepreg and/or polyimide. The dielectric layer 910 may include a photo-imageable dielectric. However, different implementations may use different materials for the dielectric layer.

Stage 4 illustrates a state after a plurality of cavities 913 is formed in the dielectric layer 910. The plurality of cavities 913 may be formed using an etching process (e.g., photo etching process), a laser process, an exposure process and/or a development process.

Stage 5 illustrates a state after interconnects 922 are formed in and over the dielectric layer 910, including in and over the plurality of cavities 913. For example, a via, pad and/or traces may be formed. A lithography process, a plating process, a strip process and/or an etching process may be used to form the interconnects.

Stage 6, as shown in FIG. 9B, illustrates a state after a dielectric layer 920 is formed over the dielectric layer 910 and the plurality of interconnects 922. A deposition and/or lamination process may be used to form the dielectric layer 920. The dielectric layer 920 may include prepreg and/or polyimide. The dielectric layer 920 may include a photo-imageable dielectric. However, different implementations may use different materials for the dielectric layer.

Stage 7, illustrates a state after a plurality of cavities 923 is formed in the dielectric layer 940. The dielectric layer 940 may represent the dielectric layer 910 and/or the dielectric layer 920. The plurality of cavities 923 may be formed using an etching process (e.g., photo etching process), a laser process, an exposure process and/or a development process.

Stage 8 illustrates a state after interconnects 932 are formed in and over the dielectric layer 940, including in and over the plurality of cavities 923. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Metallization Portion

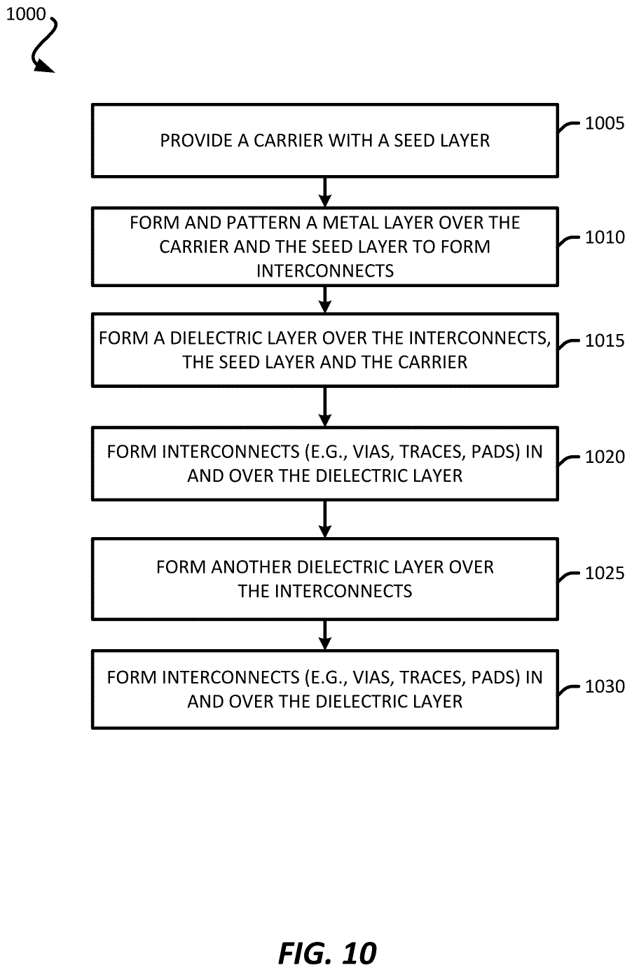

In some implementations, fabricating a metallization portion includes several processes. FIG. 10 illustrates an exemplary flow diagram of a method 1000 for providing or fabricating a metallization portion. In some implementations, the method 1000 of FIG. 10 may be used to provide or fabricate any of the metallization portions of the disclosure. For example, the method 1000 of FIG. 10 may be used to fabricate the metallization portion 102.

It should be noted that the method 1000 of FIG. 10 may combine one or more processes in order to simplify and/or clarify the method for providing or fabricating a metallization portion. In some implementations, the order of the processes may be changed or modified.

The method provides (at 1005) a carrier with a seed layer. Stage 1 of FIG. 9A, illustrates and describes an example of a state after a carrier 900 is provided. A seed layer 901 may be located over the carrier 900. The carrier 900 may be replaced with other components and/or materials.

The method forms and patterns (at 1010) a plurality of interconnects. Stage 2 of FIG. 9A, illustrates and describes an example of a state after a plurality of interconnects 912 are formed. The interconnects 912 may be located over the seed layer 901. A lithography process, a plating process, a strip process and/or an etching process may be used to form the plurality of interconnects 912. The interconnects 912 may represent at least some of the interconnects from the plurality of metallization interconnects 121.

The method forms (at 1010) a dielectric layer. Stage 3 of FIG. 9A, illustrates and describes an example of a state after a dielectric layer 910 is formed over the carrier 900, the seed layer 901 and the plurality of interconnects 912. A deposition and/or lamination process may be used to form the dielectric layer 910. The dielectric layer 910 may include prepreg and/or polyimide. The dielectric layer 910 may include a photo-imageable dielectric. However, different implementations may use different materials for the dielectric layer.

The method forms (at 1020) a plurality of interconnects. Forming a plurality of interconnects may including forming a plurality of cavities in a dielectric layer and a performing a plating process. Stage 4 of FIG. 9A, illustrates and describes an example of a state after a plurality of cavities 913 is formed in the dielectric layer 910. The plurality of cavities 913 may be formed using an etching process (e.g., photo etching process), a laser process, an exposure process and/or a development process.

Stage 5 of FIG. 9A, illustrates and describes an example of a state after interconnects 922 are formed in and over the dielectric layer 910, including in and over the plurality of cavities 913. For example, a via, pad and/or traces may be formed. A lithography process, a plating process, a strip process and/or an etching process may be used to form the interconnects.

The method forms (at 1025) another dielectric layer. Stage 6 of FIG. 9B, illustrates and describes an example of a state after a dielectric layer 920 is formed over the dielectric layer 910 and the plurality of interconnects 922. A deposition and/or lamination process may be used to form the dielectric layer 920. The dielectric layer 920 may include prepreg and/or polyimide. The dielectric layer 920 may include a photo-imageable dielectric. However, different implementations may use different materials for the dielectric layer.

The method forms (at 1030) a plurality of interconnects. Forming a plurality of interconnects may including forming a plurality of cavities in a dielectric layer and a performing a plating process. Stage 7 of FIG. 9B, illustrates and describes an example of a state after a plurality of cavities 923 is formed in the dielectric layer 940. The dielectric layer 940 may represent the dielectric layer 910 and/or the dielectric layer 920. The plurality of cavities 923 may be formed using an etching process (e.g., photo etching process), a laser process, an exposure process and/or a development process.

Stage 8 of FIG. 9B, illustrates and describes an example of a state after interconnects 932 are formed in and over the dielectric layer 940, including in and over the plurality of cavities 923. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

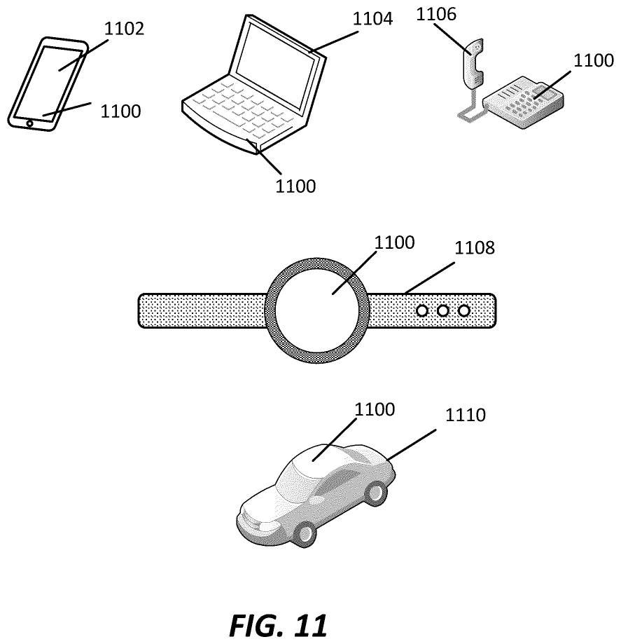

FIG. 11 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1102, a laptop computer device 1104, a fixed location terminal device 1106, a wearable device 1108, or automotive vehicle 1110 may include a device 1100 as described herein. The device 1100 may be, for example, any of the devices and/or integrated circuit (IC) packages described herein. The devices 1102, 1104, 1106 and 1108 and the vehicle 1110 illustrated in FIG. 11 are merely exemplary. Other electronic devices may also feature the device 1100 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-2, 3A-3D, 4-6, 7A-7C, 8, 9A-9B, and 10-11 may be rearranged and/or combined into a single component, process, feature or function or embodied in several components, processes, or functions. Additional elements, components, processes, and/or functions may also be added without departing from the disclosure. It should also be noted FIGS. 1-2, 3A-3D, 4-6, 7A-7C, 8, 9A-9B, and 10-11 and its corresponding description in the present disclosure is not limited to dies and/or ICs. In some implementations, FIGS. 1-2, 3A-3D, 4-6, 7A-7C, 8, 9A-9B, and 10-11 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.
Aspect 1: A package comprising a substrate; a first integrated device coupled to the substrate through at least a first plurality of solder interconnects; an encapsulation layer at least partially encapsulating the first integrated device, wherein the encapsulation layer includes a cavity; a metallization portion coupled to the first integrated device; and a first passive device coupled to the metallization portion through at least a second plurality of solder interconnects, wherein the first passive device is located at least partially in the cavity of the encapsulation layer.
Aspect 2: The package of aspect 1, wherein the metallization portion is coupled to and touching a back side of the first integrated device.
Aspect 3: The package of aspects 1 through 2, wherein the metallization portion is located between the first integrated device and the first passive device.
Aspect 4: The package of aspects 1 through 3, wherein the first passive device includes a deep trench capacitor device.
Aspect 5: The package of aspects 1 through 4, wherein the metallization portion includes a first plurality of metallization interconnects configured as an inductor.
Aspect 6: The package of aspects 1 through 5, wherein an electrical path between the first passive device and the first integrated device includes a back side of the first integrated device.
Aspect 7: The package of aspects 1 through 6, wherein an electrical path between the first integrated device and the first passive device comprises (i) at least one metallization interconnect from the metallization portion and (ii) at least one solder interconnect from the second plurality of solder interconnects.
Aspect 8: The package of aspects 1 through 7, further comprising a second passive device coupled to the metallization portion through at least a third plurality of solder interconnects, wherein the second passive device is located at least partially in the cavity of the encapsulation layer.
Aspect 9: The package of aspect 8, wherein a first electrical path between the first integrated device and the first passive device comprises (i) at least one metallization interconnect from the metallization portion and (ii) at least one solder interconnect from the second plurality of solder interconnects, and wherein a second electrical path between the first integrated device and the second passive device comprises (i) at least one other metallization interconnect from the metallization portion and (ii) at least one other solder interconnect from the second plurality of solder interconnects.
Aspect 10: The package of aspect 8, wherein the metallization portion comprises a first plurality of metallization interconnects configured as a first inductor, wherein the first inductor is electrically coupled to the first passive device, and a second plurality of metallization interconnects configured as a second inductor, wherein the second inductor is electrically coupled to the second passive device.
Aspect 11: The package of aspects 1 through 10, wherein the substrate comprises an interposer portion; a first metallization portion coupled to the interposer portion; and a second metallization portion coupled to the interposer portion.
Aspect 12: The package of aspects 1 through 11, further comprising a second integrated device coupled to the substrate through at least a third plurality of solder interconnects; and a third integrated device coupled to the substrate through at least a fourth plurality of solder interconnects.
Aspect 13: The package of aspect 12, wherein the second integrated device and the third integrated device each have a thickness that is greater than a thickness of the first integrated device.
Aspect 14: The package of aspect 12, wherein the first passive device vertically overlaps with the first integrated device, and wherein the first passive device is located laterally to the second integrated device and the third integrated device.
Aspect 15: The package of aspects 1 through 14, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.
Aspect 16: A method for fabricating a package. The method provides a substrate. The method couples a first integrated device to the substrate through at least a first plurality of solder interconnects. The method forms an encapsulation layer that at least partially encapsulates the first integrated device, wherein the encapsulation layer includes a cavity. The method forms a metallization portion that is coupled to the first integrated device. The method couples a first passive device to the metallization portion through at least a second plurality of solder interconnects, wherein the first passive device is located at least partially in the cavity of the encapsulation layer.
Aspect 17: The method of aspect 16, wherein the metallization portion is coupled to and touching a back side of the first integrated device.
Aspect 18: The method of aspects 16 through 17, wherein the metallization portion is located between the first integrated device and the first passive device.
Aspect 19: The method of aspects 16 through 18, wherein the first passive device includes a deep trench capacitor device.
Aspect 20: The method of aspects 16 through 19, wherein the metallization portion includes a first plurality of metallization interconnects configured as an inductor.
Aspect 21: The package of aspects 1 through 15, wherein the package is implemented in a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a substrate;
a first integrated device coupled to the substrate through at least a first plurality of solder interconnects;
an encapsulation layer at least partially encapsulating the first integrated device, wherein the encapsulation layer includes a cavity;
a metallization portion coupled to the first integrated device; and
a first passive device coupled to the metallization portion through at least a second plurality of solder interconnects, wherein the first passive device is located at least partially in the cavity of the encapsulation layer.

2. The package of claim 1, wherein the metallization portion is coupled to and touching a back side of the first integrated device.

3. The package of claim 1, wherein the metallization portion is located between the first integrated device and the first passive device.

4. The package of claim 1, wherein the first passive device includes a deep trench capacitor device.

5. The package of claim 1, wherein the metallization portion includes a first plurality of metallization interconnects configured as an inductor.

6. The package of claim 1, wherein an electrical path between the first passive device and the first integrated device includes a back side of the first integrated device.

7. The package of claim 1, wherein an electrical path between the first integrated device and the first passive device comprises (i) at least one metallization interconnect from the metallization portion and (ii) at least one solder interconnect from the second plurality of solder interconnects.

8. The package of claim 1, further comprising a second passive device coupled to the metallization portion through at least a third plurality of solder interconnects, wherein the second passive device is located at least partially in the cavity of the encapsulation layer.

9. The package of claim 8,
wherein a first electrical path between the first integrated device and the first passive device comprises (i) at least one metallization interconnect from the metallization portion and (ii) at least one solder interconnect from the second plurality of solder interconnects, and
wherein a second electrical path between the first integrated device and the second passive device comprises (i) at least one other metallization interconnect from the metallization portion and (ii) at least one other solder interconnect from the second plurality of solder interconnects.

10. The package of claim 8, wherein the metallization portion comprises:
a first plurality of metallization interconnects configured as a first inductor, wherein the first inductor is electrically coupled to the first passive device, and
a second plurality of metallization interconnects configured as a second inductor, wherein the second inductor is electrically coupled to the second passive device.

11. The package of claim 1, wherein the substrate comprises:
an interposer portion;
a first metallization portion coupled to the interposer portion; and
a second metallization portion coupled to the interposer portion.

12. The package of claim 1, further comprising:
a second integrated device coupled to the substrate through at least a third plurality of solder interconnects; and
a third integrated device coupled to the substrate through at least a fourth plurality of solder interconnects.

13. The package of claim 12, wherein the second integrated device and the third integrated device each have a thickness that is greater than a thickness of the first integrated device.

14. The package of claim 12,
wherein the first passive device vertically overlaps with the first integrated device, and
wherein the first passive device is located laterally to the second integrated device and the third integrated device.

15. The package of claim 1, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

16. A method for fabricating a package, comprising
providing a substrate;
coupling a first integrated device to the substrate through at least a first plurality of solder interconnects;
forming an encapsulation layer that at least partially encapsulates the first integrated device, wherein the encapsulation layer includes a cavity;
forming a metallization portion that is coupled to the first integrated device; and
coupling a first passive device to the metallization portion through at least a second plurality of solder interconnects, wherein the first passive device is located at least partially in the cavity of the encapsulation layer.

17. The method of claim 16, wherein the metallization portion is coupled to and touching a back side of the first integrated device.

18. The method of claim 16, wherein the metallization portion is located between the first integrated device and the first passive device.

19. The method of claim 16, wherein the first passive device includes a deep trench capacitor device.

20. The method of claim 16, wherein the metallization portion includes a first plurality of metallization interconnects configured as an inductor.
